(19) United States
(12) Patent Application Publication
(10) Pub. No.: US 2007/0181420 A1
(43) Pub. Date: Aug. 9, 2007

(54) WAFER STAGE HAVING AN ENCAPSULATED CENTRAL PEDESTAL PLATE

(76) Inventors: Ming-Tung Wang, Ping-Tung Hsien (TW); Sheng-Yuan Chen, Tai-Chung City (TW); Chin-Yung Liu, Chia-Yi Hsien (TW); Peng-Yih Peng, Hsin-Chu Hsien (TW); Shang-Kuang Wu, Hsin-Chu Hsien (TW); Wen-Kun Lo, Chiayi City (TW); Fu-Yi Lai, Tai-Chung City (TW); Cheng-Bang Fan, Hsin-Chu Hsien (TW); Jeng-Hung Lue, Kao-Hsiung Hsien (TW); Chien-Chih Ho, Chia-Yi Hsien (TW)

Correspondence Address: NORTH AMERICA INTELLECTUAL PROPERTY CORPORATION, P.O. BOX 506, MERRIFIELD, VA, 22116, US

(21) Appl. No.: 11/307,428

(22) Filed: Feb. 7, 2006

(51) Int. Cl. C23C 14/00

(52) U.S. Cl. 204/298.02

(57) ABSTRACT

A wafer stage includes a bottom insulator plate secured on a bottom portion of the processing chamber; a central pedestal plate mounted on the bottom insulator plate; and a removable top insulator cover having a chamber fittingly accommodating the central pedestal plate and the bottom insulator plate, wherein the top insulator cover has a flat top surface on which a wafer is placed.

### BACKGROUND OF THE INVENTION

1. Field of the Invention

The present invention relates generally to an apparatus for manufacturing a semiconductor device and, more particularly, to a wafer stage having an encapsulated central pedestal plate, which is used in a pre-clean chamber of a PVD or CVD cluster tool.

2. Description of the Prior Art

Physical vapor deposition (PVD) and chemical vapor deposition (CVD) processes are known in the art. A PVD or CVD cluster tool typically comprises multiple chambers including a pre-clean chamber, in which a pre-clean process is performed to remove undesirable surface oxides such as silicon dioxide or metal oxides from the surfaces of the substrates. The pre-clean process is ordinarily carried out before the substrates are subjected to the primary PVD or CVD process.

FIG. 1 is a schematic view of a prior art wafer stage used in a pre-clean chamber. As shown in FIG. 1, the wafer stage 10 includes a quartz insulator plate 12 and a central pedestal plate 14. The central pedestal plate 14 is made from conductive materials such as titanium. The quartz insulator plate 12 has a recess 22 that fittingly accommodates the central pedestal plate 14. The central pedestal plate 14 has flat upper surface 24 that typically extends above the uppermost surface 26 of the quartz insulator plate 12. During the pre-clean process, a wafer 20 is placed on the flat upper surface 24 of the central pedestal plate 14.

The uppermost surface 26 of the quartz insulator plate 12 is an annular perimeter area located around the central pedestal plate 14. The central pedestal plate 14 further comprises an annular perimeter surface 28 formed around the uppermost surface 26 with a height slightly lower than the surface 26. A gap 32 is formed between the uppermost surface 26 of the quartz insulator plate 12 and a bottom surface of the wafer 20.

The central pedestal plate 14 is a part of a process kit that system operators periodically clean during routine maintenance. It is desirable that a process kit has a long useful lifetime, so that the downtime of the system will be a small percentage of the overall processing time. One disadvantage of the above-described prior art is that the pre-clean process can cause particles to accumulate in the gap 32, and on the uppermost surface 26 and the annular perimeter surface 28 of the quartz insulator plate 12. A seam 36 formed between the central pedestal plate 14 and the quartz insulator plate 12 deteriorates the particle problem.

In light of the above, there is a need in this industry to provide an improved wafer stage of a pre-clean chamber that is capable of minimizing particle contamination in a pre-clean process prior to the primary CVD or PVD process. Further, it would be desirable to extend the specified lifetime of a process kit.

### SUMMARY OF THE INVENTION

It is one object of the present invention to provide an improved wafer stage having an encapsulated central pedestal plate, which is used in a pre-clean chamber of a PVD or CVD cluster tool.

According to the claimed invention, a wafer stage for placing a wafer in a processing chamber. The wafer stage includes a bottom insulator plate secured on a bottom portion of the processing chamber; a central pedestal plate mounted on the bottom insulator plate; and a removable top insulator cover having a chamber fittingly accommodating the central pedestal plate and the bottom insulator plate, wherein the top insulator cover has a flat top surface for placing the wafer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 is a schematic, cross-sectional view of a prior art wafer stage used in a pre-clean chamber;

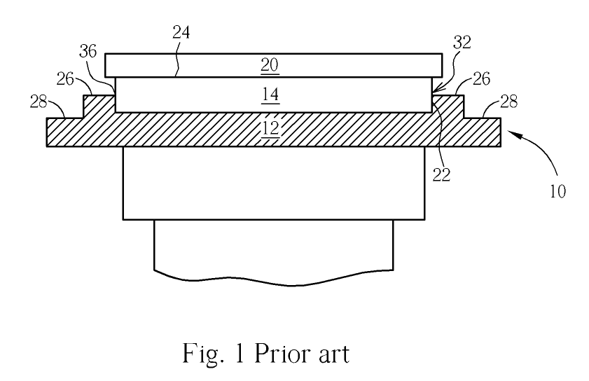

FIG. 2 is a schematic, cross-sectional view of a wafer stage used in a pre-clean chamber in accordance with one preferred embodiment of this invention;

FIG. 3 is a perspective view of the wafer stage before the wafer is loaded according to this invention; and

FIG. 4 is an exploded perspective view showing the parts of the wafer stage according to this invention.

### DETAILED DESCRIPTION

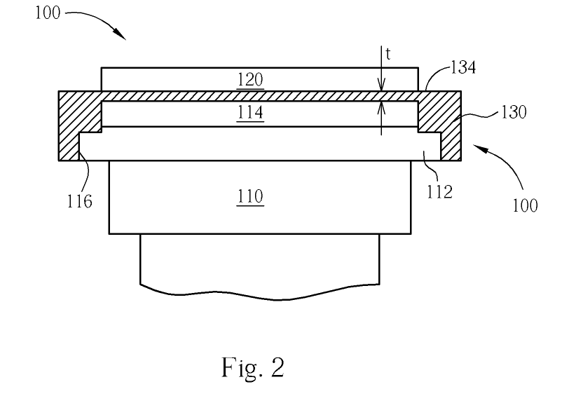

Please refer to FIG. 2. FIG. 2 is a schematic, cross-sectional view of a wafer stage 100 used in a pre-clean chamber in accordance with one preferred embodiment of this invention. According to the preferred embodiment, the pre-clean chamber is a wafer processing chamber of a PVD or CVD cluster tool such as ENDURA 5500 available from Applied Materials, Inc., Santa Clara, Calif. It is understood that the wafer stage 100 is not drawn to scale.

As shown in FIG. 2, the wafer stage 10 includes a central pedestal plate 114 that is encapsulated by a bottom insulator piece 112 and a monolithic top insulator piece 130. The central pedestal plate 114 may contain titanium. During a pre-clean process, a wafer 120 is placed on a flat upper surface 134 of the top insulator piece 130. The bottom insulator piece 112 is secured on a base portion 110. The central pedestal plate 114 is mounted on a flat surface of the bottom insulator piece 112. The top insulator piece 130 is removable and is periodically replaced by the system operators.

According to the preferred embodiment, both the bottom insulator piece 112 and the top insulator piece 130 are made of quartz. However, other suitable insulating materials may be employed. In another case, the bottom insulator piece 112 and the top insulator piece 130 may be made of different insulating materials.

The top insulator piece 130 functions as a cover that has a chamber 116 fittingly accommodates the central pedestal plate 114 and the bottom insulator piece 112 such that plasma is not in direct contact with the central pedestal plate 114 and the bottom insulator piece 112 during a pre-clean process. By doing this, the central pedestal plate 114 can be kept in very clean condition all the time and thus the period for changing the central pedestal plate 114 is extended.

It is one salient feature of the present invention that the thickness t of the top insulator piece 130 between the wafer and the central pedestal plate 114 is preferably less than 5 millimeters in order not to obstruct the generation of plasma or interfere the output of a bias RF power provided through the central pedestal plate 114.

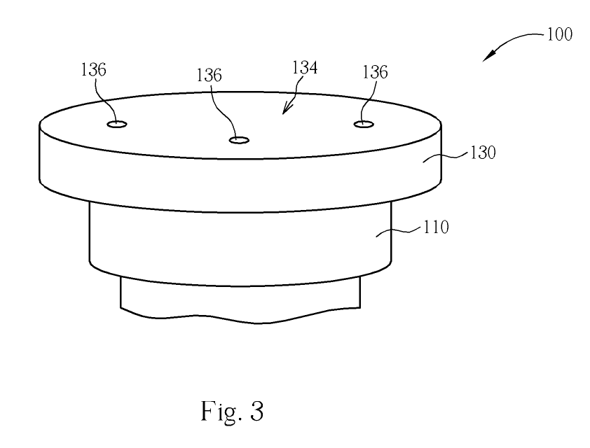

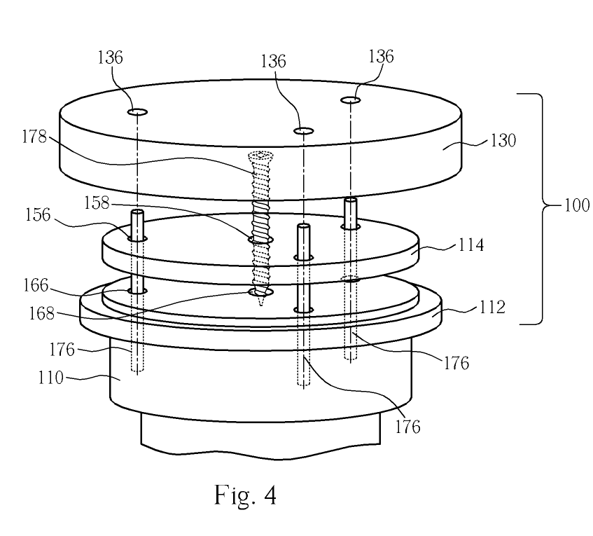

Please refer to FIG. 3 and FIG. 4. FIG. 3 is a perspective view of the wafer stage 100 before the wafer is loaded according to this invention. FIG. 4 is an exploded perspective view showing the parts of the wafer stage 100 according to this invention. As shown in FIGS. 3 and 4, the top insulator piece 130 further comprises three through holes 136 on the flat upper surface 134. The three through holes 136 on the flat upper surface 134 of the top insulator piece 130 and the corresponding through holes 156 and 166 disposed on respective central pedestal plate 114 and bottom insulator piece 112 allow the passage of three retractable lift pins 176. The three lift pins 176 protrude from the flat upper surface 134 of the top insulator piece 130 to receive and hold the wafer from a transfer robot (not shown), then descend and at last the wafer is placed on the flat upper surface 134.

Further, the central pedestal plate 114 and bottom insulator piece 112 have respective central through holes 158 and 168. The central pedestal plate 114 and bottom insulator piece 112 are secured to the base portion 110 by using a screw 178 via the through holes 158 and 168. The screw 178 is electrically connected to a power supply that provides the central pedestal plate 114 with desired bias power in a pre-clean process.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A wafer stage for placing a wafer in a processing chamber, comprising:
a bottom insulator plate secured on a bottom portion of said processing chamber;
a central pedestal plate mounted on said bottom insulator plate; and
a removable top insulator cover having a chamber fittingly accommodating said central pedestal plate and said bottom insulator plate, wherein said top insulator cover has a flat upper surface for placing said wafer.

2. The wafer stage for placing a wafer in a processing chamber according to claim 1 wherein said processing chamber is a pre-clean chamber of a PVD or CVD cluster tool.

3. The wafer stage for placing a wafer in a processing chamber according to claim 1 wherein said top insulator cover is a monolithic piece of quartz.

4. The wafer stage for placing a wafer in a processing chamber according to claim 1 wherein said bottom insulator plate is made of quartz.

5. The wafer stage for placing a wafer in a processing chamber according to claim 1 wherein said top insulator cover has a thickness of less than 5 millimeters between said wafer and said central pedestal plate.

6. The wafer stage for placing a wafer in a processing chamber according to claim 1 wherein said central pedestal plate contains titanium.

7. A wafer stage of a pre-clean chamber, comprising:
a bottom insulator plate;
a central pedestal plate; and
a removable top insulator cover having a chamber fittingly accommodating said central pedestal plate and said bottom insulator plate, wherein said removable top insulator cover and said bottom insulator plate encapsulate said central pedestal plate.

8. The wafer stage of a pre-clean chamber according to claim 7 wherein said top insulator cover is a monolithic piece of quartz.

9. The wafer stage of a pre-clean chamber according to claim 7 wherein said bottom insulator plate is made of quartz.

10. The wafer stage of a pre-clean chamber according to claim 7 wherein aid top insulator cover has a thickness of less than 5 millimeters between said wafer and said central pedestal plate.

11. The wafer stage of a pre-clean chamber according to claim 7 wherein said central pedestal plate contains titanium.
